(19) United States
(12) Patent Application Publication
(10) Pub. No.: US 2023/0288482 A1
(43) Pub. Date: Sep. 14, 2023

(54) DIAGNOSIS APPARATUS, DIAGNOSIS METHOD, AND DIAGNOSIS PROGRAM FOR ROTARY MACHINE

(71) Applicant: MITSUBISHI HEAVY INDUSTRIES, LTD., Tokyo (JP)

(72) Inventors: Yohei CHISHIKI, Tokyo (JP); Koki TATEISHI, Tokyo (JP); Takashi SONODA, Tokyo (JP)

(73) Assignee: MITSUBISHI HEAVY INDUSTRIES, LTD., Tokyo (JP)

(21) Appl. No.: 18/013,476

(22) PCT Filed: Feb. 8, 2021
(86) PCT No.: PCT/JP2021/004490

§ 371 Date: Dec. 28, 2022

(30) Foreign Application Priority Data
Jul. 31, 2020 (JP) 2020-130180

(51) Int. Cl. G01R 31/34

(52) U.S. Cl. CPC G01R 31/343

(57) ABSTRACT

A diagnosis apparatus for a rotary machine includes: a feature acquisition part configured to acquire, from a current waveform of a current measured during rotation of a rotary machine including a motor or a generator, a plurality of features each representing a characteristic of the current; and an abnormality determination part configured to determine whether there is an abnormality in the rotary machine on the basis of a divergence between a distribution of each of the plurality of features or a multi-dimensional distribution of the plurality of features and a reference distribution of each of the plurality of features or a reference multi-dimensional distribution during normal operation of the rotary machine.

### TECHNICAL FIELD

The present disclosure relates to a diagnosis apparatus, a diagnosis method, and a diagnosis program for a rotary machine.

The present application claims priority based on Japanese Patent Application No. 2020-130180 filed Jul. 31, 2020, the entire content of which is incorporated herein by reference.

### BACKGROUND ART

It has been proposed to detect an abnormality in a rotary machine on the basis of a current value measured during rotation of the rotary machine.

For example, Patent Document 1 discloses a diagnosis apparatus for diagnosing a machine including a rotary machine on the basis of current measured during rotation of the rotary machine. In this diagnosis apparatus, an abnormality in the machine is detected by comparing the distribution of current effective values acquired from the measured current with the distribution of current effective values acquired from current measured during normal operation of the rotary machine.

### CITATION LIST

### Patent Literature

Patent Document 1: JP6619908B

### SUMMARY

### Problems to be Solved

Depending on the properties of the rotary machine and the type of abnormality, even when an abnormality occurs in the rotary machine, there may not be much effect on the distribution of feature (e.g., current effective value) obtained from the measured current. Therefore, if abnormality detection of the rotary machine is based only on the distribution of one feature (current effective value in Patent Document 1) obtained from the measured current as described in Patent Document 1, it may not be possible to detect an abnormality appropriately depending on the properties of the rotary machine and the type of abnormality to be detected.

In view of the above, an object of at least one embodiment of the present invention is to provide a diagnosis apparatus, a diagnosis method, and a diagnosis program for a rotary machine whereby it is possible to detect an abnormality in the rotary machine appropriately.

### Solution to the Problems

A diagnosis apparatus for a rotary machine according to at least one embodiment of the present invention includes: a feature acquisition part configured to acquire, from a current waveform of a current measured during rotation of a rotary machine including a motor or a generator, a plurality of features each representing a characteristic of the current; and an abnormality determination part configured to determine whether there is an abnormality in the rotary machine on the basis of a divergence between a distribution of each of the plurality of features or a multi-dimensional distribution of the plurality of features and a reference distribution of each of the plurality of features or a reference multi-dimensional distribution during normal operation of the rotary machine.

Further, a diagnosis method for a rotary machine according to at least one embodiment of the present invention includes: a step of acquiring, from a current waveform of a current measured during rotation of a rotary machine including a motor or a generator, a plurality of features each representing a characteristic of the current; and a step of determining whether there is an abnormality in the rotary machine on the basis of a divergence between a distribution of each of the plurality of features or a multi-dimensional distribution of the plurality of features and a reference distribution of each of the plurality of features or a reference multi-dimensional distribution during normal operation of the rotary machine.

Further, a diagnosis program for a rotary machine according to at least one embodiment of the present invention is configured to cause a compute to execute: a process of acquiring, from a current waveform of a current measured during rotation of a rotary machine including a motor or a generator, a plurality of features each representing a characteristic of the current; and a process of determining whether there is an abnormality in the rotary machine on the basis of a divergence between a distribution of each of the plurality of features or a multi-dimensional distribution of the plurality of features and a reference distribution of each of the plurality of features or a reference multi-dimensional distribution during normal operation of the rotary machine.

### Advantageous Effects

At least one embodiment of the present invention provides a diagnosis apparatus, a diagnosis method, and a diagnosis program for a rotary machine whereby it is possible to detect an abnormality in the rotary machine appropriately.

### BRIEF DESCRIPTION OF DRAWINGS

FIG. 1 is a schematic diagram of a rotary machine to which a diagnosis apparatus is applied according to an embodiment.

FIG. 2 is a schematic diagram of a diagnosis apparatus according to an embodiment.

FIG. 3 is a flowchart of a diagnosis method according to an embodiment.

FIG. 4 is a flowchart of a diagnosis method according to an embodiment.

FIG. 5 is a graph showing an example of current waveform acquired by a diagnosis apparatus according to an embodiment.

FIG. 6 is a graph visually showing an example of a probability distribution of effective value of current of the rotary machine.

FIG. 7 is a graph visually showing an example of a multi-dimensional probability distribution of effective value and crest factor of current of the rotary machine.

FIG. 8A is an example of a multi-dimensional probability distribution of effective value and crest factor calculated based on measured current of the rotary machine.

FIG. 8B is an example of a probability distribution of effective value obtained in the same situation as in FIG. 8A.

FIG. 8C is an example of a probability distribution of crest factor obtained in the same situation as in FIG. 8A.

FIG. 9A is an example of a multi-dimensional probability distribution of effective value and crest factor calculated based on measured current of the rotary machine.

FIG. 9B is an example of a probability distribution of effective value obtained in the same situation as in FIG. 9A.

FIG. 9C is an example of a probability distribution of crest factor obtained in the same situation as in FIG. 9A.

FIG. 10 is a chart showing an example of current waveform acquired by a diagnosis apparatus according to an embodiment.

FIG. 11 is a flowchart for describing the process of acquiring divided waveforms in a diagnosis method according to an embodiment.

FIG. 12 is a graph showing an example of current waveform acquired by a diagnosis apparatus according to an embodiment.

FIG. 13 is a graph showing an example of current waveform acquired by a diagnosis apparatus according to an embodiment.

FIG. 14 is a graph showing an example of current waveform acquired by a diagnosis apparatus according to an embodiment.

FIG. 15 is a graph showing an example of current waveform acquired by a diagnosis apparatus according to an embodiment.

### DETAILED DESCRIPTION

Embodiments of the present invention will now be described in detail with reference to the accompanying drawings. It is intended, however, that unless particularly identified, dimensions, materials, shapes, relative positions, and the like of components described in the embodiments shall be interpreted as illustrative only and not intended to limit the scope of the present invention.

(Configuration of Diagnosis Apparatus)

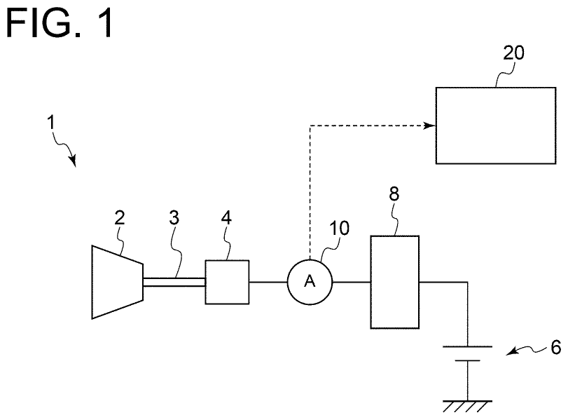

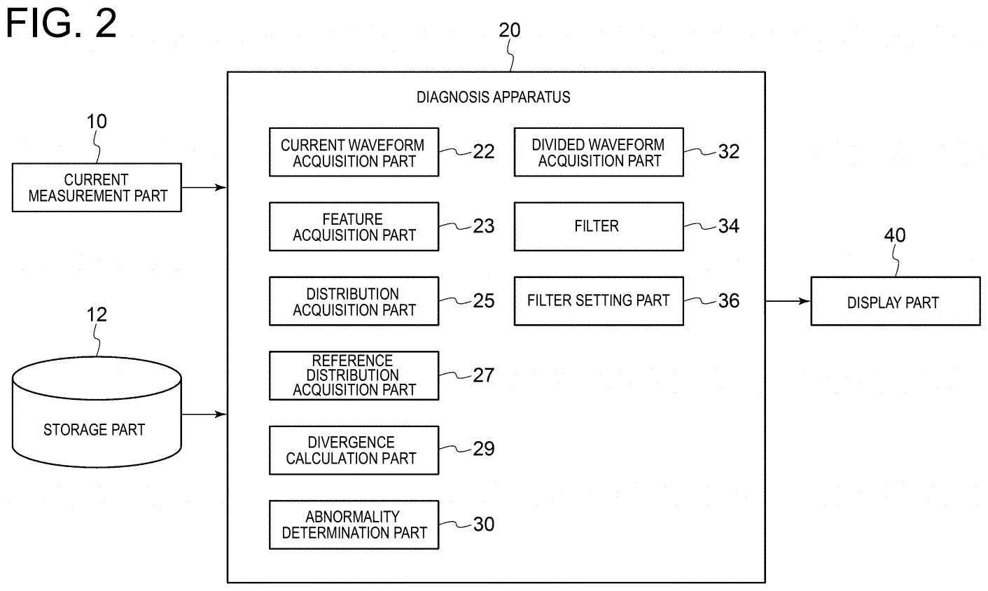

FIG. 1 is a schematic diagram of a rotary machine to which a diagnosis apparatus is applied according to an embodiment. FIG. 2 is a schematic diagram of a diagnosis apparatus according to an embodiment. The diagnosis apparatus according to some embodiments is a diagnosis apparatus for diagnosing a rotary machine including a motor or a generator.

In some embodiments, the rotary machine to be diagnosed includes a motor. A rotary machine 1 shown in FIG. 1 is an example of the rotary machine including a motor, and includes a compressor 2 for compressing a fluid and a motor 4 for driving the compressor 2. The compressor 2 is connected to the motor 4 via an output shaft 3 of the motor 4. The motor 4 is driven by power supply.

The motor 4 may be configured to be driven by AC power. In the exemplary embodiment shown in FIG. 1, DC power from a DC power source 6 (e.g., storage battery) is converted to AC power by an inverter 8 and supplied to the motor 4. In other embodiments, AC power from an AC power supply may be supplied to the motor 4.

In some embodiments, the rotary machine to be diagnosed includes a generator. Such a rotary machine may include, for example, a turbine configured to be driven by a fluid and a generator configured to be driven by the turbine. The generator may be configured to generate AC power.

A diagnosis apparatus 20 is configured to diagnose the rotary machine 1 on the basis of a current measured by a current measurement part 10 during rotation of the rotary machine 1.

The current measurement part 10 is configured to measure a current supplied to the motor (for example, motor 4 in FIG. 1) included in the rotary machine 1 or a current output from the generator included in the rotary machine 1. The current measurement part 10 may be configured to measure a winding current of the motor or the generator included in the rotary machine 1.

The diagnosis apparatus 20 is configured to receive a signal indicating a current measurement value from the current measurement part 10. The diagnosis apparatus 20 may be configured to receive a signal indicating a current measurement value from the current measurement part 10 at a specified sampling period. Further, the diagnosis apparatus 20 is configured to process the signal received from the current measurement part 10 and determine whether there is an abnormality in the rotary machine 1. The diagnosis result by the diagnosis apparatus 20 may be displayed on a display part 40 (e.g., display; see FIG. 2).

An abnormality in the rotary machine 1 to be diagnosed by the diagnosis apparatus is an abnormality in the rotary machine 1 that can affect the current measurement value from the current measurement part 10. Examples of such abnormalities include misalignment (center deviation), cavitation, belt loosening, and ground faults in the rotary machine 1.

As shown in FIG. 2, the diagnosis apparatus 20 according to an embodiment includes a current waveform acquisition part 22, a feature acquisition part 23, a distribution acquisition part 25, a reference distribution acquisition part 27, a divergence calculation part 29, an abnormality determination part 30, a divided waveform acquisition part 32, a filter 34, and a filter setting part 36.

The diagnosis apparatus 20 includes a calculator equipped with a processor (e.g., CPU), a storage device (memory device; e.g., RAM), an auxiliary storage part, and an interface. The diagnosis apparatus 20 receives a signal indicating a current measurement value from the current measurement part 10 via the interface. The processor is configured to process the signal thus received. In addition, the processor is configured to process programs loaded into the storage device. Thereby, the function of each functional unit (current waveform acquisition part 22, etc.) is implemented.

The processing contents in the diagnosis apparatus 20 may be implemented as programs executed by the processor. The programs may be stored in the auxiliary memory. When executed, these programs are loaded into the storage device. The processor reads out the programs from the storage device to execute instructions included in the programs, respectively.

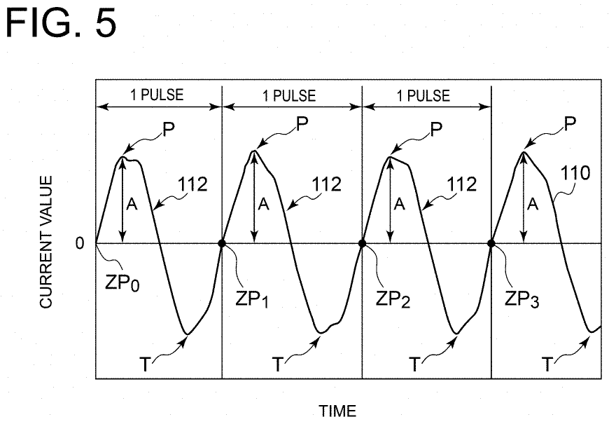

The current waveform acquisition part 22 is configured to acquire a current waveform 110 (see FIG. 5) representing a change in measured current value over time on the basis of the signal received from the current measurement part 10.

The feature acquisition part 23 is configured to acquire a plurality of features (feature values) each representing a characteristic of the measured current from the current waveform 110 acquired by the current waveform acquisition part 22. The feature acquisition part 23 may be configured to acquire an effective value of the current for each of divided waveforms acquired by the divided waveform acquisition part 32, which will be described later.

The features of the current acquired by the feature acquisition part 23 may be, for example, a difference between maximum and minimum values of the current in the current waveform 110 (or in a divided waveform acquired from the current waveform) acquired by the current waveform acquisition part 22, an effective value of the current (the square root of the mean of the squares), an average value of the current (the mean of absolute values), a skewness of the current (the third-order moment around the mean normalized (divided) by the standard deviation cubed), or a crest factor (maximum value/effective value) of the current.

The feature acquisition part 23 may be configured to two or more of the above-described multiple types of features from the current waveform 110 as the plurality of features. In this case, the combination of two or more features may be for example, but not limited to, a combination of the effective value and the crest factor.

Alternatively, when the rotary machine 1 includes a three-phase motor or a three-phase generator, the feature acquisition part 23 may be configured to acquire, as the plurality of features, one or more features for each of the three-phase currents (winding currents) of the three-phase motor or the three-phase generator. In this case, the type of one or more features may be for example, but not limited to, the effective value.

The distribution acquisition part 25 is configured to calculate a distribution of each of the plurality of features acquired by the feature acquisition part 23 or a multi-dimensional distribution of the plurality of features. The multi-dimensional distribution of two features is a two-dimensional distribution.

The distribution of each of the plurality of features acquired by the distribution acquisition part 25 may be a probability distribution of each of the plurality of features. The multi-dimensional distribution of the plurality of features acquired by the distribution acquisition part 25 may be a multi-dimensional probability distribution of the plurality of features.

The reference distribution acquisition part 27 is configured to acquire a reference distribution of each of the plurality of features (the same features as those of the distributions acquired by the distribution acquisition part 25) during normal operation of the rotary machine 1 or a reference multi-dimensional distribution of the plurality of features. The reference distribution or the reference multi-dimensional distribution acquired by the reference distribution acquisition part 27 is acquired in advance during normal operation of the rotary machine 1 (when no abnormality has occurred). The reference distribution or the reference multi-dimensional distribution may be stored in the storage part 12 (see FIG. 2). The reference distribution acquisition part 27 may acquire the reference distribution or the reference multi-dimensional distribution by reading it from the storage part 12. The storage part 12 may include a storage device of a computer that constitutes the diagnosis apparatus 20, or may include a storage device provided at a remote location.

The reference distribution of each of the plurality of features acquired by the reference distribution acquisition part 27 may be a probability distribution (reference probability distribution) of each of the plurality of features. Further, the reference multi-dimensional distribution of the plurality of features acquired by the reference distribution acquisition part 27 may be a multi-dimensional probability distribution (reference multi-dimensional probability distribution) of the plurality of features.

The divergence calculation part 29 is configured to acquire a divergence between each distribution or the multi-dimensional distribution calculated by the distribution acquisition part 25 and each reference distribution or the reference multi-dimensional distribution acquired by the reference distribution acquisition part 27.

The abnormality determination part 30 is configured to determine whether there is an abnormality in the rotary machine 1 (that is, determine the presence or absence of an abnormality in the rotary machine 1) on the basis of the divergence acquired by the divergence calculation part 29.

In some embodiments, the divergence calculation part 29 may be configured to calculate, as the above-described divergence, a distance between the probability distribution of each of the plurality of features calculated by the distribution acquisition part 25 and the reference probability distribution of each of the plurality of features during the normal operation acquired by the reference distribution acquisition part 27. Further, the abnormality determination part 30 may determine whether there is an abnormality in the rotary machine 1 on the basis of the plurality of distances thus calculated. The above-described distance is an index value that can quantify the difference between two probability distributions (probability density functions), and may be a Kullback-Leibler distance, a Pearson distance, a relative Pearson distance, or a L² distance between the probability distribution of a certain feature and the reference probability distribution of the same feature.

In an embodiment, the abnormality determination part 30 may determine whether there is an abnormality in the rotary machine 1, using the largest one of the plurality of distances calculated (i.e., respective distances of the distributions of the plurality of features). For example, the abnormality determination part may be configured to determine that an abnormality has occurred in the rotary machine 1 when the largest one of the calculated distances is not less than a threshold, and may be determine that the rotary machine 1 is normal (no abnormality has occurred) when the largest one is less than the threshold.

In some embodiments, the divergence calculation part 29 may be configured to calculate, as the above-described divergence, a distance between the multi-dimensional probability distribution of the plurality of features calculated by the distribution acquisition part and the reference multi-dimensional probability distribution of the plurality of features during the normal operation acquired by the reference distribution acquisition part 27. Further, the abnormality determination part 30 may determine whether there is an abnormality in the rotary machine 1 on the basis of the distance thus calculated. For example, the abnormality determination part 30 may be configured to determine that an abnormality has occurred in the rotary machine 1 when the calculated distance is not less than a threshold, and may be determine that the rotary machine 1 is normal (no abnormality has occurred) when the distance is less than the threshold. The above-described distance is an index value that can quantify the difference between two probability distributions (probability density functions), and may be a Kullback-Leibler distance, a Pearson distance, a relative Pearson distance, or a L² distance between the multi-dimensional probability distribution and the reference multi-dimensional probability distribution of the plurality of features.

The divided waveform acquisition part 32 is configured to acquire a plurality of divided waveforms 112 by dividing the current waveform 110 acquired by the current waveform acquisition part 22 by a specified number of pulses (see FIG. 5). Here, each divided waveform 112 obtained by dividing the current waveform by a specified number of pulses is a portion of the current waveform 110 that includes a specified number of pairs of peaks and troughs appearing in the current waveform 110 (i.e., waveform for the specified number of cycles approximately). For example, the divided waveform 112 with one pulse is obtained by extracting, from the current waveform 110 acquired by the current waveform acquisition part 22, a portion that includes one pair of a peak and a trough appearing in the current waveform (i.e., waveform for one cycle approximately) (see FIG. 5).

The filter 34 is a filter for reducing noise components (high frequency components) from the signal received from the current measurement part 10. The filter setting part 36 is configured to be able to change settings such as the time constant of the filter 34.

According to the findings of the present inventors, when an abnormality occurs in the rotary machine 1, the magnitude of the effect on each of the distributions of the plurality of features that can be acquired from the measured current varies depending on the properties of the rotary machine 1 and the type of abnormality. In this regard, the diagnosis apparatus 20 according to the above-described embodiments determines whether there is an abnormality in the rotary machine 1 on the basis of the divergence between the distribution of each of the plurality of features acquired from the current waveform 110 of the measured current and the reference distribution of each of the plurality of features or the divergence between the multi-dimensional distribution of the plurality of features and the reference multi-dimensional distribution of the plurality of features. Therefore, as compared to the abnormality determination based on the divergence between the distribution and the reference distribution of a single feature, it is possible to detect an abnormality more exhaustively for the characteristics of the rotary machine 1 and the types of abnormality. Thus, it is possible to detect an abnormality in the rotary machine 1 more appropriately.

(Diagnosis Flow of Rotary Machine)

Hereinafter, the diagnosis flow for a rotary machine according to an embodiment will be described more specifically. The following describes the case where the above-described diagnosis apparatus 20 is used to execute a diagnosis method for a rotary machine according to an embodiment, but in some embodiments, another apparatus may be used to execute the diagnosis method for a rotary machine.

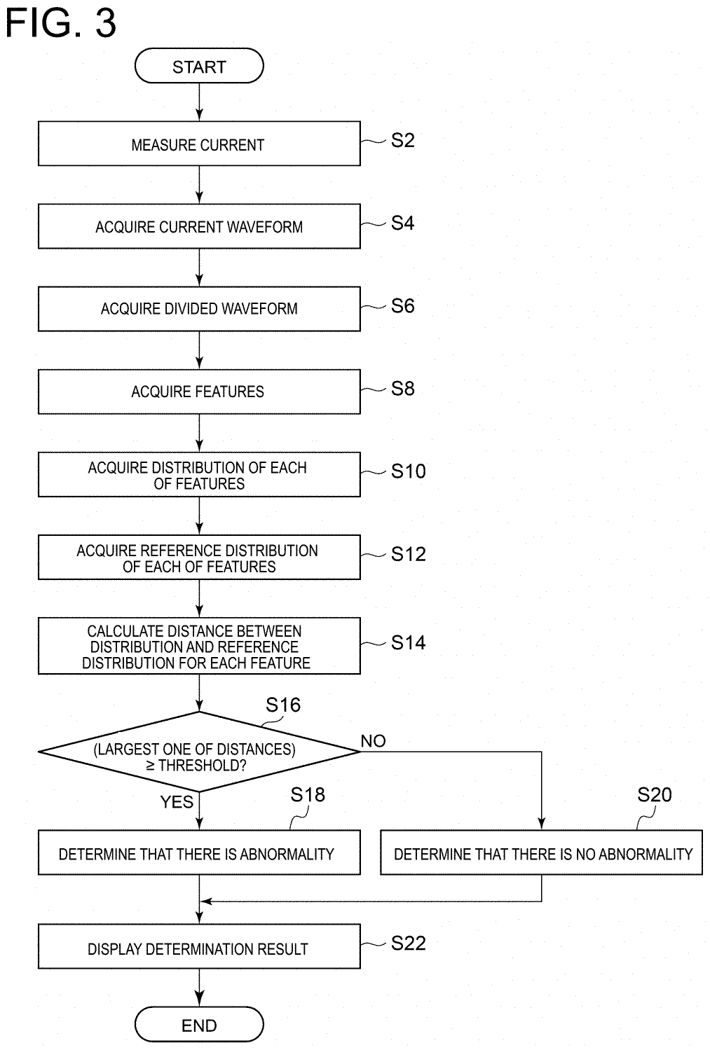

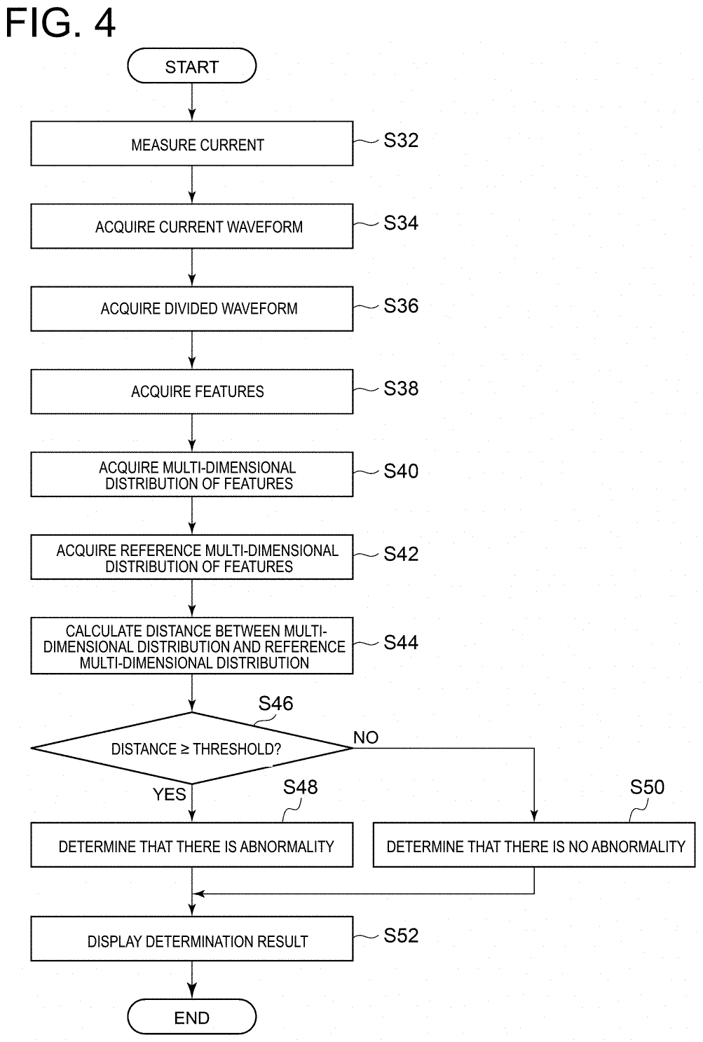

FIGS. 3 and 4 are each a flowchart of the diagnosis method according to an embodiment.

In the embodiment shown in FIG. 3, first, using the current measurement part 10, a current is measured during rotation of the rotary machine 1 (S2). The current measured in step S2 may be a current supplied to the motor or a current output from the generator.

Then, a current waveform 110 representing a change in measured current value over time is acquired by the current waveform acquisition part 22 on the basis of a signal received from the current measurement part 10 (signal indicating a current measurement value) (S4). Here, FIG. 5 is a graph showing an example of the current waveform 110 acquired by the current waveform acquisition part 22 (diagnosis apparatus 20) according to an embodiment. As shown in FIG. 5, the current waveform 110 acquired in step S4 is an AC waveform in which peaks P (positive peaks) and troughs T (negative peaks) appear alternately.

Then, the current waveform 110 acquired in step S4 is divided by a specified number of pulses to acquire a plurality of divided waveforms 112 by the divided waveform acquisition part 32 (S6). In step S6, the plurality of divided waveforms 112 (divided waveforms with one pulse; see FIG. 5) may be acquired by dividing the current waveform 110 by one pulse. In step S6, the plurality divided waveform 112 may be acquired by dividing the current waveform 110 at each period related to the rotation speed of the rotary machine 1 or at each period related to the cycle of the alternating current to extract portions included in each period from the current waveform 110. Alternatively, as will be described later, the plurality of divided waveforms 112 may be acquired by dividing the current waveform 110 on the basis of zero-crossing points grasped from the current waveform 110.

The following describes the case where, in step S6, the current waveform 110 is divided by one pulse to acquire the plurality of divided waveforms 112. However, the following description can also be applied to the case where the current waveform 110 is divided by every two or more pulses to acquire divided waveforms.

Then, for each of the divided waveforms 112 obtained in step S6, a plurality of features each representing a characteristic of the measured current is acquired by the feature acquisition part 23 (S8). The feature acquisition part 23 may be configured to acquire a plurality of features for each of the divided waveforms acquired by the divided waveform acquisition part 32, which will be described later. Here, as an example, the effective value, which is the first feature, and the crest factor, which is the second feature, are acquired as the plurality of features.

Here, the effective value Iᵣₘₛ of the current of each divided waveform 112 can be calculated as the square root of the mean (time mean) of the squares of current measurement values I of each divided waveform 112. If the current measurement value is obtained at a specified sampling period, the effective value Iᵣₘₛ of the current of the divided waveform 112 can be expressed by the following equation (A), using the current values Iₜ at multiple measurement points in each divided waveform 112 and the time length T from the start point to the end point of each divided waveform 112.

$$\begin{matrix}( Expression 1 ) & \\ {I}_{r n s} = \sqrt{\frac{1}{T} {{\sum }_{t}}^{T} {I}_{t}^{2}} & ( A )\end{matrix}$$

Further, the crest factor I_{ef} of the current of each divided waveform 112 can be calculated as a ratio of the maximum value Iₘₐₓ to the effective value Iᵣₘₛ of the current measurement values I of each divided waveform 112. That is, the crest factor I_{ef} can be expressed by the following equation.

I_{ef}=Iₘₐₓ/Iᵣₘₛ (B)

Then, a distribution of each of the plurality of features (effective value Iᵣₘₛ and crest factor I_{ef}) is acquired by the distribution acquisition part 25 for the plurality of divided waveforms 112 acquired in step S8. Here, a probability distribution of effective values Iᵣₘₛ of the plurality of divided waveforms 112 obtained in step S8 and a probability distribution of crest factors I_{ef} of the plurality of divided waveforms 112 obtained in step S8 are acquired.

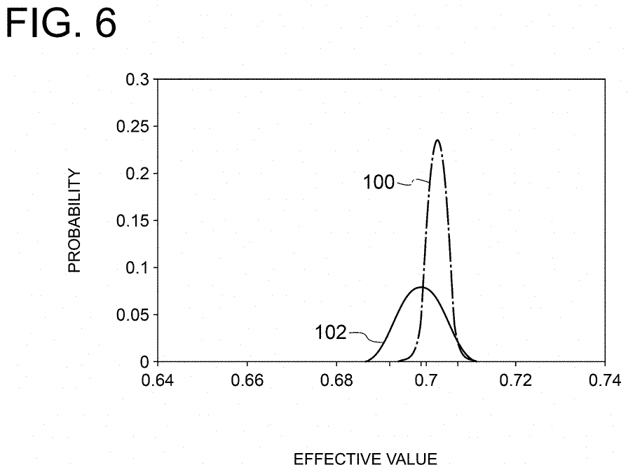

FIG. 6 is a graph visually showing an example of the probability distribution of the effective value of the current of the rotary machine 1. This probability distribution is acquired on the basis of the effective value of each of the plurality of divided waveforms 112 obtained by dividing the current waveform 110. In the graph of FIG. 6, the horizontal axis represents the effective value and the vertical axis represents the probability.

In step S10, for example, a probability distribution shown by the curve 102 is obtained as the probability distribution of the effective value of the measured current. The curve 100 in FIG. 6 shows a probability distribution of the effective value during normal operation the rotary machine 1. According to findings of the present inventors, when an abnormality occurs in the rotary machine 1 including the motor (for example, motor 4 in FIG. 1) or the generator, disturbance occurs in the measured current waveform 110, which may increase the dispersion of the distribution of features (such as effective value) obtained from the current waveform 110. Thus, when an abnormality occurs in the rotary machine 1, the probability distribution is usually different from normal.

Although not depicted, a probability distribution of the crest factor of the measured current is also acquired in the same manner in step S10.

Then, a reference distribution, which is a distribution of each of the features of the measured current during normal operation of the rotary machine 1, is acquired by the reference distribution acquisition part 27. Here, a reference probability distribution of the effective value Iᵣₘₛ and a reference probability distribution of the crest factor I_{ef} are acquired. The reference distributions (e.g., reference probability distributions) of the effective value and crest factor may be, for example, acquired in advance and stored in the storage part 12. The reference distribution acquisition part 27 may acquire the reference distributions by reading the reference distribution of the effective value and the reference distribution of the crest factor stored in the storage part 12. The curve 100 in FIG. 6 shows an example of the reference probability distribution of the effective value.

Then, a distance between the probability distribution of each of the plurality of features calculated by the distribution acquisition part 25 and the reference probability distribution of each of the plurality of features during the normal operation acquired by the reference distribution acquisition part 27 is calculated by the divergence calculation part 29 (S14). Here, the relative Pearson distance is calculated as the distance. That is, the relative Pearson distance D1 between the probability distribution and the reference probability distribution regarding the effective value and the relative Pearson distance D2 between the probability distribution and the reference probability distribution regarding the crest factor are calculated.

When the reference probability distribution is p(x), and the probability distribution is p′(x), the relative Pearson distance between the probability distribution and the reference probability distribution can be calculated, for example, by ∫q_{α}(x)[{p(x)/q_{α}(x)}−1]²dx, where q_{α} =αp+(1−α)p′ (0≤α<1).

Then, using the plurality of distances (i.e., the relative Pearson distance D1 regarding the effective value and relative Pearson distance D2 regarding the crest factor) calculated in step S14, it is determined by the abnormality determination part 30 whether there is an abnormality in the rotary machine 1 (S16). In step S16, the largest one of the plurality of distances may be used for abnormality determination of the rotary machine 1.

For example, of the two distances D1 and D2, if the relative Pearson distance D1 regarding the effective value is the larger, the relative Pearson distance D1 regarding the effective value is used to determine whether there is an abnormality in the rotary machine 1. If the relative Pearson distance D1 is not less than a preset threshold (Yes in S16), it is determined that an abnormality has occurred in the rotary machine 1 (S18). Conversely, if the relative Pearson distance D1 is less than the threshold (No in S16), it is determined that the rotary machine 1 is normal (no abnormality has occurred) (S20).

The determination results in steps S18 and S20 may be displayed on the display part (S22).

As already described, when an abnormality occurs in the rotary machine 1, the magnitude of the effect on each of the distributions of the plurality of features that can be acquired from the measured current varies depending on the properties of the rotary machine 1 and the type of abnormality. Further, the larger the distance between the probability distribution of each of the plurality of features and the reference probability distribution of each of the plurality of features, the higher the possibility that an abnormality occurs in the rotary machine (the degree of abnormality of the rotary machine 1). In this regard, according to the above-described embodiment, an abnormality in the rotary machine 1 can be detected appropriately on the basis of the largest one (e.g., relative Pearson distance D1 regarding the effective value) of the plurality of distances acquired (the above-described relative Pearson distances D1 and D2).

Next, an embodiment shown in FIG. 4 will be described. Steps S32, S34, S36, S38, and S52 in the flowchart of FIG. 4 are the same as steps S2, S4, S6, S8, and S22 in the flowchart of FIG. 3, so explanations of these steps S2 will be omitted.

In the embodiment shown in FIG. 4, for the plurality of divided waveforms 112 acquired in step S38, a multi-dimensional distribution of the plurality of features (effective value Tᵣₘₛ and crest factor I_{ef}) is acquired by the distribution acquisition part 25 (S40). Here, a multi-dimensional probability distribution of effective values Iᵣₘₛ of the plurality of divided waveforms 112 obtained in step S38 and crest factors I_{ef} of the plurality of divided waveforms 112 obtained in step S8 is acquired. In this embodiment, two features (effective value and crest factor) are used as the plurality of features, so the multi-dimensional distribution is a two-dimensional distribution.

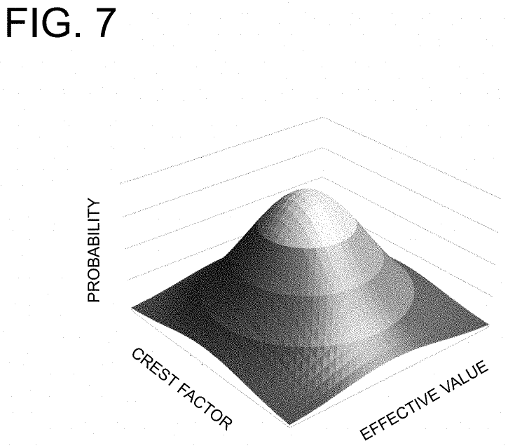

FIG. 7 is a graph visually showing an example of the multi-dimensional probability distribution of the effective value and the crest factor of the current of the rotary machine 1. This multi-dimensional probability distribution is acquired on the basis of the effective value and the crest factor of each of the plurality of divided waveforms 112 obtained by dividing the current waveform 110.

In step S40, for example, a multi-dimensional probability distribution shown in FIG. 7 is obtained as the multi-dimensional probability distribution of the effective value and the crest factor of the measured current. When an abnormality occurs in the rotary machine 1 including the motor (for example, motor 4 in FIG. 1) or the generator, disturbance occurs in the measured current waveform 110, which may increase the dispersion of the distribution of features (such as effective value or current waveform) obtained from the current waveform 110. Thus, when an abnormality occurs in the rotary machine 1, the probability distribution is usually different from normal.

Then, a reference multi-dimensional distribution, which is a distribution of the features of the measured current during normal operation of the rotary machine 1, is acquired by the reference distribution acquisition part 27. Here, a reference multi-dimensional probability distribution of the effective value Iᵣₘₛ and the crest factor I_{ef} is acquired. The reference multi-dimensional distribution (e.g., reference multi-dimensional probability distribution) of the effective value and the crest factor may be, for example, acquired in advance and stored in the storage part 12. The reference distribution acquisition part 27 may acquire the reference multi-dimensional distribution by reading the reference multi-dimensional distribution of the effective value and the crest factor stored in the storage part 12.

Then, a distance between the multi-dimensional probability distribution of the plurality of features calculated by the distribution acquisition part 25 and the reference multi-dimensional probability distribution of the plurality of features during the normal operation acquired by the reference distribution acquisition part 27 is calculated by the divergence calculation part 29 (S44). Here, the relative Pearson distance is calculated as the distance.

That is, the relative Pearson distance Dm between the multi-dimensional probability distribution and the reference multi-dimensional probability distribution regarding the effective value and the crest factor is calculated.

Then, using the distance (i.e., the relative Pearson distance Dm regarding the effective value and the crest factor) calculated in step S44, it is determined by the abnormality determination part 30 whether there is an abnormality in the rotary machine 1 (S46). If the relative Pearson distance Dm is not less than a preset threshold (Yes in S46), it is determined that an abnormality has occurred in the rotary machine 1 (S48). Conversely, if the relative Pearson distance Dm is less than the threshold (No in S46), it is determined that the rotary machine 1 is normal (no abnormality has occurred) (S50).

In the above-described embodiment, one value (e.g., the relative Pearson distance Dm) indicating the divergence is calculated for the plurality of features (e.g., the effective value and the crest factor). Therefore, the single index thus calculated is used to determine whether the rotary machine 1 is normal or abnormal, which facilitates the abnormality determination of the rotary machine 1.

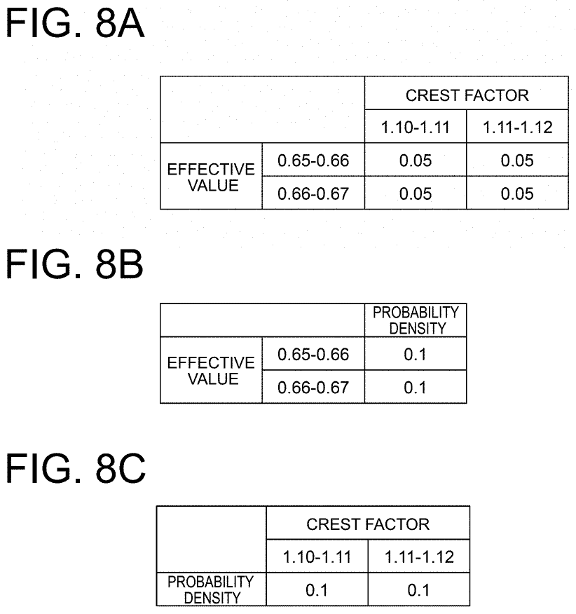

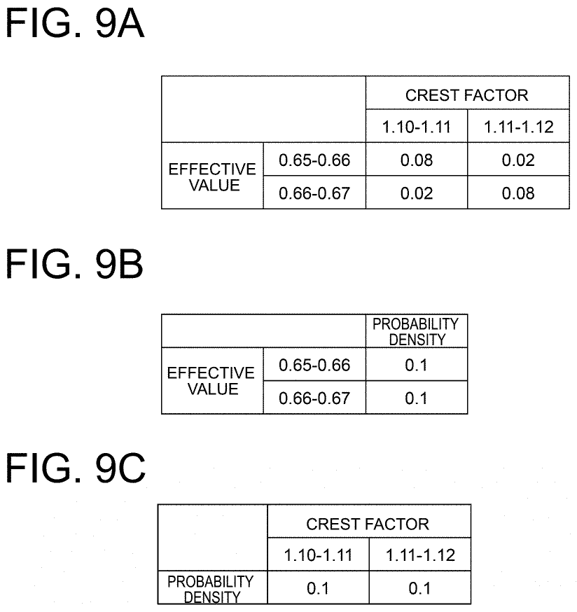

Here, FIGS. 8A and 9A are each an example of the multi-dimensional probability distribution of the effective value and the crest factor calculated based on the measured current of the rotary machine 1. Among them, FIG. 8A is a multi-dimensional probability distribution based on the measured current when the rotary machine 1 is normal, and FIG. 9A is a multi-dimensional probability distribution based on the measured current when the rotary machine 1 is abnormal. FIGS. 8B and 9B are each an example of the probability distribution of the effective value (single feature) obtained in the same situation as in FIGS. 8A and 9A. FIGS. 8C and 9C are each an example of the probability distribution of the crest factor (single feature) obtained in the same situation as in FIGS. 8A and 9A.

For simplicity of explanation, in FIGS. 8A to 9C, only partial ranges of the multi-dimensional probability distributions and probability distributions (specifically, the range of the effective value of 0.65 to 0.67, and the range of the crest factor of 1.10 to 1.12) are shown.

In the multi-dimensional probability distribution when the rotary machine 1 is normal shown in FIG. 8A, in the range shown, the probability in each cell of the table is 0.05, which is a uniform probability distribution. In contrast, in the multi-dimensional probability distribution when the rotary machine 1 is abnormal shown in FIG. 9A, in the range shown, the probability ranges from 0.02 to 0.08, which is a different probability distribution from normal (FIG. 8A). Therefore, it is possible to calculate the divergence (e.g., distance such as relative Pearson distance) between the normal multi-dimensional probability distribution (reference multi-dimensional probability distribution) and the abnormal multi-dimensional probability distribution, and to determine whether there is an abnormality in the rotary machine 1 on the basis of the divergence.

On the other hand, it is possible that, although there is a difference in the multi-dimensional probability distribution regarding a plurality of features between normal and abnormal operations of the rotary machine 1, there is no difference in the probability distribution regarding a single feature. For example, there is no difference in the probability distribution regarding the effective value (single feature) shown in FIGS. 8B and 9B between normal and abnormal operations of the rotary machine 1. Further, there is no difference in the probability distribution regarding the crest factor (single feature) shown in FIGS. 8C and 9C between normal and abnormal operations of the rotary machine 1.

Thus, even if an abnormality occurs in the rotary machine 1, the distance between the distribution (e.g., probability distribution) and the reference distribution (e.g., reference probability distribution) can be zero when focusing on only a single feature. The use of the distance calculated in this way may not be sufficient to appropriately detect an abnormality in the rotary machine 1.

In this regard, in the embodiment described with reference to FIG. 4, since the divergence (e.g., the relative Pearson distance Dm) is calculated in relation to the plurality of features (e.g., the effective value and the crest factor), changes in the distribution of the plurality of features when an abnormality occurs in the rotary machine 1 can be grasped in more detail, compared to the case where the divergence (e.g., relative Pearson distance) is calculated for the distribution of a single feature (e.g., one of the effective value or the crest factor). Therefore, it is possible to improve the abnormality detection performance of the rotary machine 1.

In some embodiments, the diagnosis method according to the flowchart shown in FIG. 4 may be applied to diagnosing the rotary machine 1 including a three-phase motor or a three-phase generator.

That is, in this case, in step S32, current of each of the three phases of the three-phase motor or three-phase generator is measured. As a result, current measurement values for three phases are obtained. In steps S34 and S36, current waveforms and divided waveforms are acquired for each of the three-phase currents. In step S38, one or more features (e.g., effective values) are acquired for each of the three-phase currents as the plurality of features. In step S40, a multi-dimensional distribution of the features (e.g., effective values) of the three-phase currents is acquired. When one feature is used, the multi-dimensional distribution is a three-dimensional distribution. In step S42, a reference multi-dimensional distribution of the features (e.g., effective values) of the three-phase currents is acquired. In step S44, the divergence (distance) between the multi-dimensional distribution and the reference multi-dimensional distribution is calculated. Then, in steps S46 to S50, it is determined whether there is an abnormality in the rotary machine 1 on the basis of the divergence.

According to the above-described embodiment, since features corresponding to each of the three-phase currents of the three-phase motor or three-phase generator are acquired as the plurality of features and the distance between the multi-dimensional probability distribution and the reference multi-dimensional probability distribution of these features is acquired, it is possible to detect an abnormality in the rotary machine 1 including the three-phase motor or three-phase generator appropriately on the basis of the distance acquired.

In some embodiments, in steps S6, S36, the divided waveform acquisition part 32 may acquire a plurality of divided waveforms 112 by dividing the current waveform 110 acquired in step S4 at a plurality of zero-crossing points ZP (e.g., ZP₀ to ZP₃ in FIG. 5). Here, the zero-crossing point is a point of the current waveform where the current passes through zero and the sign of the current changes in the same direction (from negative to positive, or from positive to negative). The zero-crossing points ZP₀ to ZP₃ in FIG. 5 are points where the current passes through zero and the sign of the current changes from negative to positive.

In the case of the current waveform 110 shown in FIG. 5, for example, portions between pairs of adjacent zero-crossing points (e.g., between ZP₀ and ZP₁, between ZP₁ and ZP₂, etc.) can be obtained as the divided waveforms 112.

When dividing the current waveform 110, it is conceivable to divide the current waveform by a specified frequency (such as frequency associated with the rotation speed of the rotary machine), but in this case, the number of samples per period may not be stable, depending on the sampling interval of the measurement device or the like. In this regard, according to the above-described embodiment, the current waveform 110 is divided at the zero-crossing points. Thus, it is possible to obtain a plurality of divided waveforms 112 whose current values are zero at the start point (zero-crossing point) and the end point (i.e., zero-crossing point). Therefore, for each of the plurality of divided waveforms 112 thus obtained, it is possible to acquire the plurality of features appropriately in steps S8, S38.

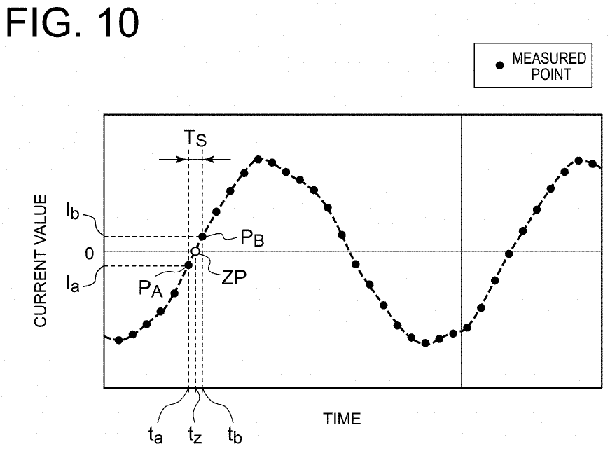

FIG. 10 is a chart showing an example of the current waveform 110 acquired in steps S4, S34. In an embodiment, the current waveform 110 obtained in steps S4, S34, as shown in FIG. 10, is represented as a curve connecting current measurement values acquired at a specified sampling period Ts. In an embodiment, in steps S6, S36, the divided waveform acquisition part 32 may identify the zero-crossing points ZP by linear interpolation of two measurement values with different signs (e.g., measurement values at measurement points P_{A} and P_{B} in FIG. 10).

In the example shown in FIG. 10, the current value passes through zero during a period between the measurement time ta at the measurement point PA, where the sign of the measured current is negative, and the measurement time tb at the measurement point PB, where the sign of the measured current is positive, but there is no measurement point with zero current value in this period. In this case, the time t_{z} of the zero-crossing point ZP between the measurement points P_{A} and P_{B} can be identified by linear interpolation based on the time ta and measured current value Iₐ of the measurement point P_{A} and the time t_{b} and measured current value I_{b} of the measurement point P_{B}.

As described above, current measurement values may be acquired as discrete measurement values at each predetermined sampling period. In this regard, in the above-described embodiment, the zero-crossing points ZP can be identified by linear interpolation of two measurement values with different signs (e.g., P_{A} and P_{B}) among the plurality of current measurement values acquired at the specified sampling period Ts. Thus, even if the plurality of discrete current measurement values does not include a measurement point with zero current value, the current waveform 110 can be divided into the divided waveforms 112 appropriately.

In some embodiments, in steps S4, S34, the current waveform acquisition part 22 may reduce noise components (high frequency components) from the signal received from the current measurement part 10 (signal indicating a current measurement value) with a filter 34 to acquire the current waveform 110. In an embodiment, in steps S6, S36, the divided waveform acquisition part 32 may identify the zero-crossing points ZP from the current waveform 110 obtained on the basis of the signal processed by the filter 34.

In a current waveform obtained from a signal containing noise, points with zero current value may randomly appear in addition to the inherent (i.e., noise-free) zero-crossing points ZP due to waveform disturbance caused by noise. In this regard, in the above-described embodiment, since the zero-crossing points ZP are identified on the basis of the signal from which noise components have been reduced by the filter 34, the divided waveforms 112 can be obtained by dividing the current waveform 110 more appropriately on the basis of the zero-crossing points ZP thus identified.

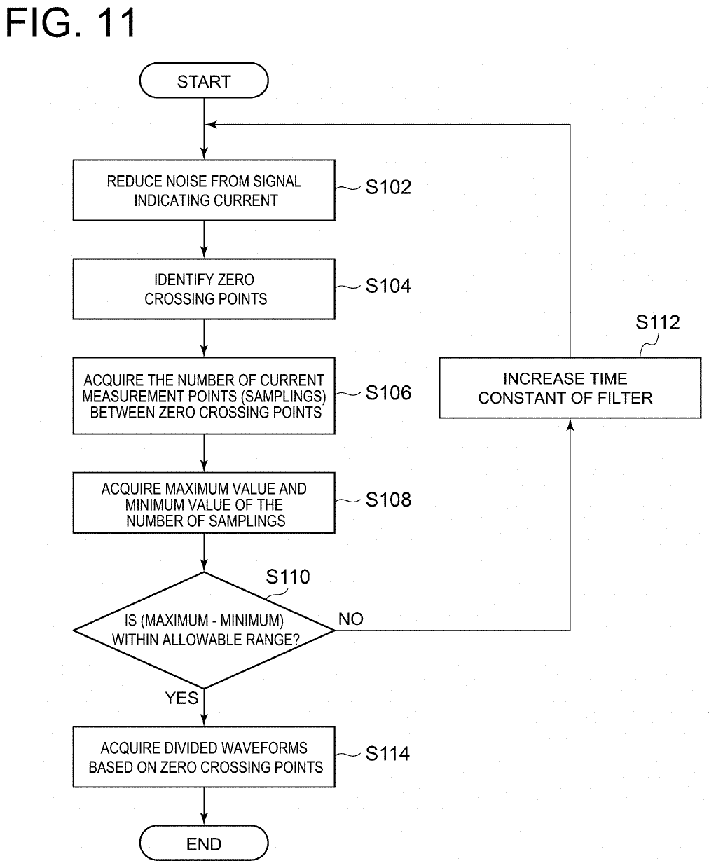

FIG. 11 is a flowchart for describing the process of acquiring divided waveforms in the diagnosis method and the diagnosis apparatus according to an embodiment.

As shown in FIG. 11, in an embodiment, with the filter 34, noise is reduced from the signal indicating the current measurement value measured in step S2 to obtain a current waveform 110 (S102, S4 in FIG. 3, S34 in FIG. 4). Then, a plurality of zero-crossing points ZP are identified from the obtained current waveform 110 (S104). In step S104, as described above, the linear interpolation method may be used.

Then, the number of current measurement points (number of samples) included between each zero-crossing point of the plurality of zero-crossing points ZP is acquired (S106). Further, the maximum and minimum values of the number of current measurement points included between each zero-crossing point are acquired (S108).

Then, it is determined whether the difference between the maximum and minimum values obtained in step S108 is within an allowable range (S110). If the difference is outside the allowable range (No in S110), the filter setting part 36 increases the time constant of the filter 34 (S112) and returns to step S102. Then, steps S102 to S108 are repeated using the filter 34 with the new time constant set.

On the other hand, if the difference is within the allowable range in step S110 (Yes in S110), a plurality of divided waveforms are obtained on the basis of the current waveform 110 and the zero-crossing points ZP obtained in the last steps S102 and S104 (S114, S6 in FIG. 3, S36 in FIG. 4).

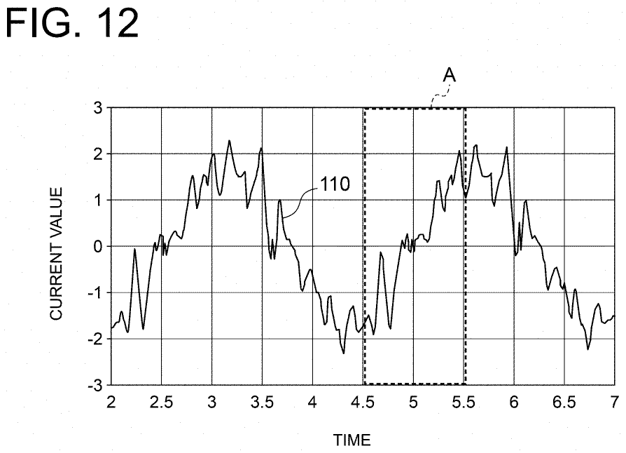

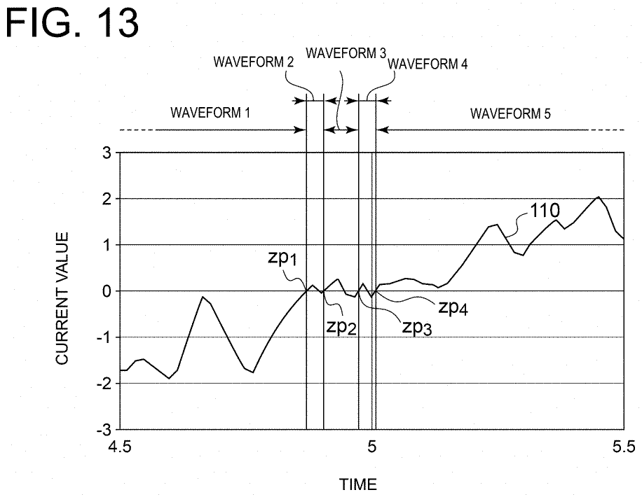

Here, FIGS. 12 and 13 are graphs showing an example of the current waveform 110 when the difference between the maximum and minimum values obtained in step S108 is outside the allowable range (No in step S108). FIG. 13 is an enlarged view of the portion A shown in FIG. 12.

The current waveform shown in FIGS. 12 and 13 contains a large amount of noise, and due to waveform disturbance caused by noise, many points with zero current value randomly appear in addition to the inherent zero-crossing points (zero-crossing points that would appear at a period corresponding to the rotation speed of the rotary machine 1). For example, as shown in FIG. 13, zero-crossing points zp1 to zp4 are contained in a relatively narrow time range (range of 4.5 to 5.5 on the horizontal axis in the graph). The period of this portion A (see FIG. 12) originally includes only one point (zero-crossing point) where the current value changes from negative to positive (based on the rotation speed of the rotary machine 1). If the current waveform is divided based on these zero-crossing points zp1 to zp4, many waveforms with random period (e.g., waveforms 1 to 5 shown in FIG. 13) are obtained as divided waveforms, and appropriate divided waveforms cannot be obtained.

In this case, there is a large variation in the time length between zero-crossing points (time length of waveforms 1 to 5 in FIG. 13). Therefore, variation in the number of current measurement points (number of samples) included between each zero-crossing point is also large, and the difference between the maximum and minimum values of the number of samples is large. Therefore, by changing the time constant of the filter 34 so that the difference between the maximum and minimum values of the number of current measurement points (number of samples) included between each zero-crossing point falls within an allowable range (steps S110 to S112), it is possible to reduce variation in the number of current measurement points (number of samples) included between each zero-crossing point.

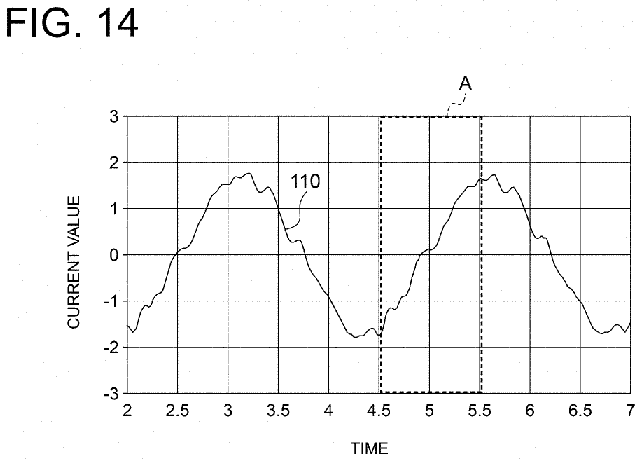

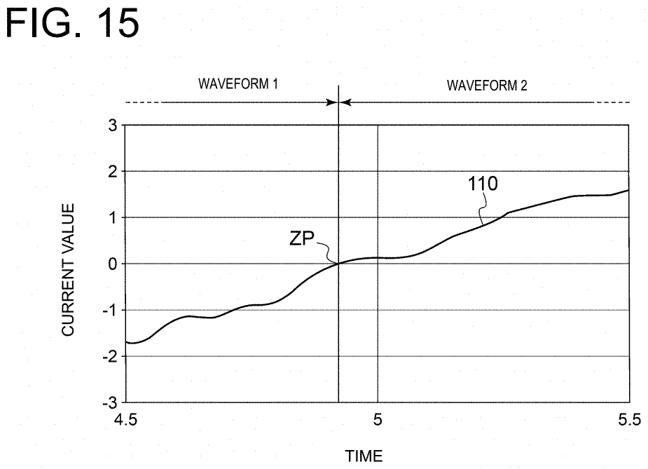

Here, FIGS. 14 and 15 are graphs showing an example of the current waveform 110 when the difference between the maximum and minimum values obtained in step S108 is within the allowable range. FIG. 15 is an enlarged view of the portion A shown in FIG. 14. As can be seen by comparing FIGS. 12 and 14 or FIGS. 13 and 15, noise in the current waveform 110 is reduced in FIGS. 14 and 15 compared to FIGS. 12 and 13, and the portion A contains only one zero-crossing point ZP. This indicates that increasing the time constant of the filter 34 appropriately makes it possible to extract from the current waveform 110 only the inherent zero-crossing points ZP (zero-crossing points that would appear at a period corresponding to the rotation speed of the rotary machine 1). By dividing the current waveform on the basis of the plurality of zero-crossing points ZP appropriately extracted, the divided waveforms can be obtained appropriately.

As described above, when the signal contains noise, points with zero current value appear randomly in addition to the inherent zero-crossing points ZP. For this reason, the divided waveforms obtained on the basis of such apparent zero-crossing points zp may have large variations in the length from the start point to the end point (period of divided waveform) and the number of samples.

In this regard, according to the above-described embodiment, the filter setting part 36 increases the time constant of the filter 34 until the difference between the maximum and minimum values of the number of sampling measurement values of the current included in each of the divided waveforms (or between a pair of zero-crossing points in the current waveform 110) falls within the allowable range. Thus, it is possible to reduce variation in the number of sampling current measurement values included in the divided waveforms 112 obtained on the basis of the zero-crossing points ZP from the signal processed by the filter 34. Thus, it is possible to obtain the divided waveforms by dividing the current waveform 110 more appropriately.

In an embodiment, the filter setting part 36 may be configured to repeatedly increase the time constant by a predetermined amount until the difference in the number of sampling measurement values of the current included in each of the divided waveforms (or between a pair of zero-crossing points in the current waveform 110) falls within the allowable range. That is, in an embodiment, in step S112, the time constant of the filter 34 may be increased by a predetermined amount. In this case, the time constant of the filter 34 increases in proportion to the number of loops in steps S102 to S110.

According to the above-described embodiment, since the time constant is repeatedly increased by the predetermined amount until the difference between maximum and minimum values of the number of sampling measurement values of the current included in the divided waveforms (or between a pair of zero-crossing points in the current waveform) falls within the allowable range, it is possible to reliably reduce variation in the number of sampling current measurement values included in the divided waveforms 112 obtained on the basis of the zero-crossing points ZP from the signal processed by the filter 34. Thus, it is possible to obtain the divided waveforms 112 by dividing the current waveform 110 more appropriately.

The contents described in the above embodiments would be understood as follows, for instance.

(1) A diagnosis device (20) for a rotary machine (1) according to at least one embodiment of the present invention includes: a feature acquisition part (23) configured to acquire, from a current waveform of a current measured during rotation of a rotary machine including a motor (4) or a generator, a plurality of features each representing a characteristic of the current; and an abnormality determination part (30) configured to determine whether there is an abnormality in the rotary machine on the basis of a divergence between a distribution of each of the plurality of features or a multi-dimensional distribution of the plurality of features and a reference distribution of each of the plurality of features or a reference multi-dimensional distribution during normal operation of the rotary machine.

According to the findings of the present inventors, when an abnormality occurs in the rotary machine, the magnitude of the effect on each of the distributions of the plurality of features that can be acquired from the measured current varies depending on the properties of the rotary machine and the type of abnormality. In this regard, with the above configuration (1), it is determined whether there is an abnormality in the rotary machine on the basis of the divergence between the distribution of each of the plurality of features acquired from the current waveform of the measured current and the reference distribution of each of the plurality of features or the divergence between the multi-dimensional distribution of the plurality of features and the reference multi-dimensional distribution of the plurality of features. Therefore, as compared to the abnormality determination based on the divergence between the distribution and the reference distribution of a single feature, it is possible to detect an abnormality more exhaustively for the characteristics of the rotary machine and the types of abnormality. Thus, it is possible to detect an abnormality in the rotary machine more appropriately.

Additionally, in the above configuration (1), when using the multi-dimensional distribution and the reference multi-dimensional distribution of the plurality of features, one value indicating the divergence is calculated for the plurality of features. Therefore, the single index thus calculated is used to determine whether the rotary machine is normal or abnormal, which facilitates the abnormality determination of the rotary machine. Additionally, when using the multi-dimensional distribution and the reference multi-dimensional distribution of the plurality of features, since the divergence is calculated in relation to the plurality of features, changes in the distribution of the plurality of features when an abnormality occurs in the rotary machine can be grasped in more detail, compared to the case where the divergence is calculated for the distribution of a single feature. Therefore, it is possible to improve the abnormality detection performance of the rotary machine.

(2) In some embodiments, in the above configuration (1), the abnormality determination part is configured to acquire a distance between a probability distribution of each of the plurality of features and a reference probability distribution of each of the plurality of features during the normal operation, and determine whether there is an abnormality in the rotary machine on the basis of the plurality of distances acquired.

With the above configuration (2), since the distance between the probability distribution of each of the plurality of features and the reference probability distribution of each of the plurality of features is acquired as indicating the divergence between the distribution of each of the plurality of features and the reference distribution of each of the plurality of features during the normal operation of the rotary machine, it is possible to detect an abnormality in the rotary machine appropriately on the basis of the plurality of distances acquired.

(3) In some embodiments, in the above configuration (2), the abnormality determination part is configured to determine whether there is an abnormality in the rotary machine, using the largest one of the plurality of distances.

The larger the distance between the probability distribution of each of the plurality of features and the reference probability distribution of each of the plurality of features, the higher the possibility that an abnormality occurs in the rotary machine (hereinafter, also referred to as the degree of abnormality of the rotary machine). In this regard, with the above configuration (3), an abnormality in the rotary machine can be detected appropriately on the basis of the largest one of the plurality of distances acquired.

(4) In some embodiments, in the above configuration (1), the abnormality determination part is configured to acquire a distance between a multi-dimensional probability distribution of the plurality of features and a reference multi-dimensional probability distribution of the plurality of features during the normal operation, and determine whether there is an abnormality in the rotary machine on the basis of the distance acquired.

With the above configuration (4), since the distance between the multi-dimensional probability distribution of the plurality of features and the reference multi-dimensional probability distribution of the plurality of features is acquired as indicating the divergence between the multi-dimensional distribution of the plurality of features and the reference multi-dimensional distribution of the plurality of features during the normal operation of the rotary machine, it is possible to detect an abnormality in the rotary machine appropriately on the basis of the distance acquired.

(5) In some embodiments, in the above configuration (4), the rotary machine includes a three-phase motor or a three-phase generator, and the feature acquisition part is configured to acquire, as the plurality of features, one or more features corresponding to each of the three-phase currents of the three-phase motor or the three-phase generator.

With the above configuration (5), since features corresponding to each of the three-phase currents of the three-phase motor or three-phase generator are acquired as the plurality of features and the distance between the multi-dimensional probability distribution and the reference multi-dimensional probability distribution of these features is acquired, it is possible to detect an abnormality in the rotary machine including the three-phase motor or three-phase generator appropriately on the basis of the distance acquired.

(6) In some embodiments, in any one of the above configurations (2) to (5), the distance includes a Kullback-Leibler distance, a Pearson distance, a relative Pearson distance, or a L² distance.

With the above configuration (6), since the Kullback-Leibler distance, the Pearson distance, the relative Pearson distance, or the L² distance is acquired as the distance between the probability distribution of each of the plurality of features and the reference probability distribution of each of the plurality of features or the distance between the multi-dimensional probability distribution of the plurality of features and the reference multi-dimensional probability distribution of the plurality of features, it is possible to detect an abnormality in the rotary machine appropriately on the basis of the distance acquired.

(7) In some embodiments, in any one of the above configurations (1) to (6), the plurality of features includes a difference between a maximum value and a minimum value, an effective value, an average value, a skewness, or a crest factor of the current in the current waveform.

With the above configuration (7), since the difference between maximum and minimum values, the effective value, the average value, the skewness, or the crest factor of the current in the current waveform of the measured current is used as the plurality of features, by acquiring the divergence between the distribution and the reference distribution of each of these features or the divergence between the multi-dimensional distribution and the reference multi-dimensional distribution of these features, it is possible to detect an abnormality in the rotary machine appropriately on the basis of the divergence.

(8) In some embodiments, in any one of the above configurations (1) to (7), the diagnosis apparatus for a rotary machine includes a divided waveform acquisition part (32) configured to acquire a divided waveform with a specified number of pulses from the current waveform. The feature acquisition part is configured to acquire the plurality of features for each divided waveform.

With the above configuration (8), since the divided waveform with a specified number of pulses is acquired from the current waveform obtained by current measurement, by acquiring the plurality of features for each divided waveform thus obtained, it is possible to acquire the distributions or multi-dimensional distribution of the plurality of features and the reference distributions or reference multi-dimensional distribution of the plurality of features appropriately. Therefore, it is possible to acquire the divergence between the distribution and the reference distribution of each of the plurality of features or the divergence between the multi-dimensional distribution and the reference multi-dimensional distribution of the plurality of features appropriately on the basis of the distributions thus acquired, and it is possible to detect an abnormality in the rotary machine appropriately on the basis of the divergence.

(9) In some embodiments, in the above configuration (8), the divided waveform acquisition part is configured to acquire a plurality of the divided waveforms by dividing the current waveform at a plurality of zero-crossing points (ZP) of the current waveform where the current passes through zero and a sign of the current changes in the same direction.

When dividing the current waveform, it is conceivable to divide the current waveform by a specified frequency (such as frequency associated with the rotation speed of the rotary machine), but in this case, the number of samples per period may not be stable, depending on the sampling interval of the measurement device or the like. In this regard, with the above configuration (9), the current waveform is divided at the zero-crossing points of the current waveform where the current passes through zero and the sign of the current changes in the same direction (from negative to positive, or from positive to negative). As a result, it is possible to obtain a plurality of divided waveforms whose current values are zero at the start point and the end point, and for each of the plurality of divided waveforms thus obtained, it is possible to acquire the plurality of features appropriately.

(10) In some embodiments, in the above configuration (9), the current waveform is represented as a curve connecting measurement values of the current acquired at a specified sampling period. The divided waveform acquisition part is configured to identify the zero-crossing points by linear interpolation of two of the measurement values with different signs.

Current measurement values may be acquired as discrete measurement values at each predetermined sampling period. With the above configuration (10), since the zero-crossing points are identified by linear interpolation of two measurement values with different signs among the plurality of current measurement values acquired at a specified sampling period, even if the plurality of discrete current measurement values does not include a measurement point with zero current value, the current waveform can be divided into the divided waveforms appropriately.

(11) In some embodiments, in the above configuration (10), the diagnosis apparatus for a rotary machine includes a filter (34) configured to reduce or remove noise components from a signal indicating the current. The divided waveform acquisition part is configured to identify the zero-crossing points on the basis of the signal processed by the filter.

In a signal containing noise, points with zero current value may randomly appear in addition to the inherent (i.e., noise-free) zero-crossing points due to waveform disturbance caused by noise. In this regard, with the above configuration (11), since the zero-crossing points are identified on the basis of the signal from which noise components have been reduced by the filter, the divided waveforms can be obtained by dividing the current waveform more appropriately on the basis of the zero-crossing points thus identified.

(12) In some embodiments, in the above configuration (11), the diagnosis apparatus for a rotary machine includes a filter setting part (36) configured to increase a time constant of the filter so that a difference between a maximum value and a minimum value of the number of sampling measurement values of the current included in each of the plurality of divided waveforms falls within an allowable range.

As described above, when the signal contains noise, points with zero current value appear randomly in addition to the inherent zero-crossing points. For this reason, the divided waveforms obtained on the basis of such apparent zero-crossing points may have large variations in the length from the start point to the end point (period of divided waveform) and the number of samples. In this regard, with the above configuration (12), since the time constant is increased so that the difference between maximum and minimum values of the number of sampling measurement values of the current included in the plurality of divided waveforms falls within the allowable range, it is possible to reduce variation in the number of sampling current measurement values included in the divided waveforms obtained on the basis of the zero-crossing points from the signal processed by the filter. Thus, it is possible to obtain the divided waveforms by dividing the current waveform more appropriately.

(13) In some embodiments, in the above configuration (12), the filter setting part is configured to repeatedly increase the time constant by a predetermined amount until the difference falls within the allowable range.

With the above configuration (13), since the time constant is repeatedly increased by the predetermined amount until the difference between maximum and minimum values of the number of sampling measurement values of the current included in the divided waveforms falls within the allowable range, it is possible to reliably reduce variation in the number of sampling current measurement values included in the divided waveforms obtained on the basis of the zero-crossing points from the signal processed by the filter. Thus, it is possible to obtain the divided waveforms by dividing the current waveform more appropriately.

(14) A diagnosis method for a rotary machine according to at least one embodiment of the present invention includes: a step (S8, S38) of acquiring, from a current waveform of a current measured during rotation of a rotary machine including a motor or a generator, a plurality of features each representing a characteristic of the current; and a step (S16 to S20, S46 to S50) of determining whether there is an abnormality in the rotary machine on the basis of a divergence between a distribution of each of the plurality of features or a multi-dimensional distribution of the plurality of features and a reference distribution of each of the plurality of features or a reference multi-dimensional distribution during normal operation of the rotary machine.

With the above method (14), it is determined whether there is an abnormality in the rotary machine on the basis of the divergence between the distribution of each of the plurality of features acquired from the current waveform of the measured current and the reference distribution of each of the plurality of features or the divergence between the multi-dimensional distribution of the plurality of features and the reference multi-dimensional distribution of the plurality of features. Therefore, as compared to the abnormality determination based on the divergence between the distribution and the reference distribution of a single feature, it is possible to detect an abnormality more exhaustively for the characteristics of the rotary machine and the types of abnormality. Thus, it is possible to detect an abnormality in the rotary machine more appropriately.

Additionally, in the above method (14), when using the multi-dimensional distribution and the reference multi-dimensional distribution of the plurality of features, one value indicating the divergence is calculated for the plurality of features. Therefore, the single value thus calculated is used to determine whether the rotary machine is normal or abnormal, which facilitates the abnormality determination of the rotary machine. Additionally, when using the multi-dimensional distribution and the reference multi-dimensional distribution of the plurality of features, since the divergence is calculated in relation to the plurality of features, changes in the distribution of the plurality of features when an abnormality occurs in the rotary machine can be grasped in more detail, compared to the case where the divergence is calculated for the distribution of a single feature. Therefore, it is possible to improve the abnormality detection performance of the rotary machine.

(15) A diagnosis program for a rotary machine according to at least one embodiment of the present invention is configured to cause a compute to execute: a process of acquiring, from a current waveform of a current measured during rotation of a rotary machine including a motor or a generator, a plurality of features each representing a characteristic of the current; and a process of determining whether there is an abnormality in the rotary machine on the basis of a divergence between a distribution of each of the plurality of features or a multi-dimensional distribution of the plurality of features and a reference distribution of each of the plurality of features or a reference multi-dimensional distribution during normal operation of the rotary machine.

With the above program (15), it is determined whether there is an abnormality in the rotary machine on the basis of the divergence between the distribution of each of the plurality of features acquired from the current waveform of the measured current and the reference distribution of each of the plurality of features or the divergence between the multi-dimensional distribution of the plurality of features and the reference multi-dimensional distribution of the plurality of features. Therefore, as compared to the abnormality determination based on the divergence between the distribution and the reference distribution of a single feature, it is possible to detect an abnormality more exhaustively for the characteristics of the rotary machine and the types of abnormality. Thus, it is possible to detect an abnormality in the rotary machine more appropriately.

Additionally, in the above program (15), when using the multi-dimensional distribution and the reference multi-dimensional distribution of the plurality of features, one value indicating the divergence is calculated for the plurality of features. Therefore, the single value thus calculated is used to determine whether the rotary machine is normal or abnormal, which facilitates the abnormality determination of the rotary machine. Additionally, when using the multi-dimensional distribution and the reference multi-dimensional distribution of the plurality of features, since the divergence is calculated in relation to the plurality of features, changes in the distribution of the plurality of features when an abnormality occurs in the rotary machine can be grasped in more detail, compared to the case where the divergence is calculated for the distribution of a single feature. Therefore, it is possible to improve the abnormality detection performance of the rotary machine.

Embodiments of the present invention were described in detail above, but the present invention is not limited thereto, and various amendments and modifications may be implemented.

Further, in the present specification, an expression of relative or absolute arrangement such as “in a direction”, “along a direction”, “parallel”, “orthogonal”, “centered”, “concentric” and “coaxial” shall not be construed as indicating only the arrangement in a strict literal sense, but also includes a state where the arrangement is relatively displaced by a tolerance, or by an angle or a distance whereby it is possible to achieve the same function.

For instance, an expression of an equal state such as “same” “equal” and “uniform” shall not be construed as indicating only the state in which the feature is strictly equal, but also includes a state in which there is a tolerance or a difference that can still achieve the same function.

Further, an expression of a shape such as a rectangular shape or a cylindrical shape shall not be construed as only the geometrically strict shape, but also includes a shape with unevenness or chamfered corners within the range in which the same effect can be achieved.

On the other hand, an expression such as “comprise”, “include”, and “have” are not intended to be exclusive of other components.

### REFERENCE SIGNS LIST

1 Rotary machine
2 Compressor
3 Output shaft
4 Motor
6 DC power source
8 Inverter
10 Current measurement part
12 Storage part
20 Diagnosis apparatus
22 Current waveform acquisition part
23 Feature acquisition part
25 Distribution acquisition part
27 Reference distribution acquisition part
29 Divergence calculation part
30 Abnormality determination part
32 Divided waveform acquisition part
34 Filter
36 Filter setting part
40 Display part
P Peak
T Trough
ZP Zero-crossing point

1.-15. (canceled)

16. A diagnosis apparatus for a rotary machine, comprising:
a feature acquisition part configured to acquire, from a current waveform of a current measured during rotation of a rotary machine including a motor or a generator, a plurality of features each representing a characteristic of the current; and
an abnormality determination part configured to determine whether there is an abnormality in the rotary machine on the basis of a divergence between a distribution of each of the plurality of features or a multi-dimensional distribution of the plurality of features and a reference distribution of each of the plurality of features or a reference multi-dimensional distribution during normal operation of the rotary machine,
wherein the abnormality determination part is configured to acquire a distance between a probability distribution of each of the plurality of features and a reference probability distribution of each of the plurality of features during the normal operation, and determine whether there is an abnormality in the rotary machine on the basis of the plurality of distances acquired.

17. The diagnosis apparatus for a rotary machine according to claim 16,
wherein the abnormality determination part is configured to determine whether there is an abnormality in the rotary machine, using a largest one of the plurality of distances.

18. The diagnosis apparatus for a rotary machine according to claim 16,
wherein the distance includes a Kullback-Leibler distance, a Pearson distance, a relative Pearson distance, or a L² distance.

19. The diagnosis apparatus for a rotary machine according to claim 16,
wherein the plurality of features includes a difference between a maximum value and a minimum value, an effective value, an average value, a skewness, or a crest factor of the current in the current waveform.

20. The diagnosis apparatus for a rotary machine according to claim 16, comprising a divided waveform acquisition part configured to acquire a divided waveform with a specified number of pulses from the current waveform,
wherein the feature acquisition part is configured to acquire the plurality of features for each divided waveform.

21. The diagnosis apparatus for a rotary machine according to claim 20,
wherein the divided waveform acquisition part is configured to acquire a plurality of the divided waveforms by dividing the current waveform at a plurality of zero-crossing points of the current waveform where the current passes through zero and a sign of the current changes in the same direction.

22. The diagnosis apparatus for a rotary machine according to claim 21,
wherein the current waveform is represented as a curve connecting measurement values of the current acquired at a specified sampling period, and
wherein the divided waveform acquisition part is configured to identify the zero-crossing points by linear interpolation of two of the measurement values with different signs.

23. The diagnosis apparatus for a rotary machine according to claim 22, comprising a filter configured to reduce or remove noise components from a signal indicating the current,
wherein the divided waveform acquisition part is configured to identify the zero-crossing points on the basis of the signal processed by the filter.

24. The diagnosis apparatus for a rotary machine according to claim 23, comprising a filter setting part configured to increase a time constant of the filter so that a difference between a maximum value and a minimum value of the number of sampling measurement values of the current included in each of the plurality of divided waveforms falls within an allowable range.

25. The diagnosis apparatus for a rotary machine according to claim 24,
wherein the filter setting part is configured to repeatedly increase the time constant by a predetermined amount until the difference falls within the allowable range.

26. A diagnosis method for a rotary machine, comprising:
a step of acquiring, from a current waveform of a current measured during rotation of a rotary machine including a motor or a generator, a plurality of features each representing a characteristic of the current; and
a step of determining whether there is an abnormality in the rotary machine on the basis of a divergence between a distribution of each of the plurality of features or a multi-dimensional distribution of the plurality of features and a reference distribution of each of the plurality of features or a reference multi-dimensional distribution during normal operation of the rotary machine,
wherein the abnormality determination step includes acquiring a distance between a probability distribution of each of the plurality of features and a reference probability distribution of each of the plurality of features during the normal operation, and determining whether there is an abnormality in the rotary machine on the basis of the plurality of distances acquired.

27. A diagnosis program for a rotary machine for causing a compute to execute:
a process of acquiring, from a current waveform of a current measured during rotation of a rotary machine including a motor or a generator, a plurality of features each representing a characteristic of the current; and
a process of determining whether there is an abnormality in the rotary machine on the basis of a divergence between a distribution of each of the plurality of features or a multi-dimensional distribution of the plurality of features and a reference distribution of each of the plurality of features or a reference multi-dimensional distribution during normal operation of the rotary machine,
wherein the abnormality determination process includes acquiring a distance between a probability distribution of each of the plurality of features and a reference probability distribution of each of the plurality of features during the normal operation, and determining whether there is an abnormality in the rotary machine on the basis of the plurality of distances acquired.
